(19) United States
(12) Patent Application Publication
(10) Pub. No.: US 2026/0198338 A1
(43) Pub. Date: Jul. 9, 2026

(54) Semiconductor Device and Method of Making High Profile and Heavy Modules

(71) Applicant: STATS ChipPAC Management Pte. Ltd., Singapore (SG)

(72) Inventors: KyoWang Koo, Incheon (KR); JungSub Lee, Incheon (KR); InSeop Lim, Incheon (KR)

(73) Assignee: STATS ChipPAC Management Pte. Ltd., Singapore (SG)

(21) Appl. No.: 19/014,604

(22) Filed: Jan. 9, 2025

(51) Int. Cl. H01L 23/538; H01L 21/48; H01L 25/18; H10D 1/20

(52) U.S. Cl. CPC H10W 70/611; H10W 70/093; H10W 90/00; H10W 90/401; H10D 1/20

(57) ABSTRACT

A semiconductor device has a first substrate. A first semiconductor package is disposed over a first surface of the first substrate. A second semiconductor package is disposed over the first surface of the first substrate. A connector is disposed over the first surface of the first substrate. A first inductor is disposed over a second surface of the first substrate opposite the first semiconductor package. A second inductor is disposed over the second surface of the first substrate opposite the second semiconductor package. A pin header is disposed over the second surface of the first substrate opposite the connector. The first substrate is disposed over a board with the first inductor and second inductor between the first substrate and board.

### FIELD OF THE INVENTION

The present invention relates in general to semiconductor devices and, more particularly, to semiconductor devices and methods of making high profile and heavy modules.

### BACKGROUND OF THE INVENTION

Semiconductor devices are commonly found in modern electronic products. Semiconductor devices perform a wide range of functions such as signal processing, high-speed calculations, transmitting and receiving electromagnetic signals, controlling electronic devices, transforming sunlight to electricity, and creating visual images for television displays. Semiconductor devices are found in the fields of communications, power conversion, networks, computers, entertainment, and consumer products. Semiconductor devices are also found in military applications, aviation, automotive, industrial controllers, and office equipment.

Some electronic devices require bulky electrical components that are larger and heavier than typical semiconductor packages, e.g., discrete inductors. Many devices call for large inductors that are simply unable to be miniaturized due to a required number of windings or other logistical reasons. Making electronic modules or packages with these high profile and heavy components is difficult and costly in the prior art. Therefore, a need exists for new devices and methods for making high profile and heavy modules.

### BRIEF DESCRIPTION OF THE DRAWINGS

FIGS. 1a-1c illustrate a semiconductor wafer with a plurality of semiconductor die separated by a saw street;

FIGS. 2a-2g illustrate forming a sandwich board for use as a substrate for high profile and heavy modules;

FIGS. 3a-3d illustrate a first embodiment of mounting high profile and heavy components on the sandwich board;

FIGS. 4a-4d illustrate a second embodiment of mounting high profile and heavy components on the sandwich board;

FIGS. 5a-5d illustrate a third embodiment of mounting high profile and heavy components on the sandwich board;

FIG. 6 illustrates a side connector embodiment;

FIGS. 7a and 7b illustrate additional interconnect through the high profile and heavy components; and

FIGS. 8a and 8b illustrate an electronic device with the high profile and heavy module.

### DETAILED DESCRIPTION OF THE DRAWINGS

The present invention is described in one or more embodiments in the following description with reference to the figures, in which like numerals represent the same or similar elements. While the invention is described in terms of the best mode for achieving the invention's objectives, it will be appreciated by those skilled in the art that it is intended to cover alternatives, modifications, and equivalents as may be included within the spirit and scope of the invention as defined by the appended claims and their equivalents as supported by the following disclosure and drawings. The features shown in the figures are not necessarily drawn to scale. Elements assigned the same reference number in the figures have a similar function and description to each other. The terms “semiconductor die” and “die” as used herein are synonymous and refer to both the singular and plural form of the words, and accordingly, can refer to both a single semiconductor device and multiple semiconductor devices.

Semiconductor devices are generally manufactured using two complex manufacturing processes: front-end manufacturing and back-end manufacturing. Front-end manufacturing involves the formation of a plurality of die on the surface of a semiconductor wafer. Each die on the wafer contains active and passive electrical components, which are electrically connected to form functional electrical circuits. Active electrical components, such as transistors and diodes, have the ability to control the flow of electrical current. Passive electrical components, such as capacitors, inductors, and resistors, create a relationship between voltage and current necessary to perform electrical circuit functions.

Back-end manufacturing refers to cutting or singulating the finished wafer into the individual semiconductor die and packaging the semiconductor die for structural support, electrical interconnect, and environmental isolation. To singulate the semiconductor die, the wafer is scored and broken along non-functional regions of the wafer called saw streets or scribes. The wafer is singulated using a laser cutting tool or saw blade. After singulation, the individual semiconductor die are disposed on a package substrate that includes pins or contact pads for interconnection with other system components. Contact pads formed over the semiconductor die are then connected to contact pads within the package. The electrical connections can be made with conductive layers, bumps, stud bumps, conductive paste, or wirebonds. An encapsulant or other molding material is deposited over the package to provide physical support and electrical isolation. The finished package is then inserted into an electrical system and the functionality of the semiconductor device is made available to the other system components.

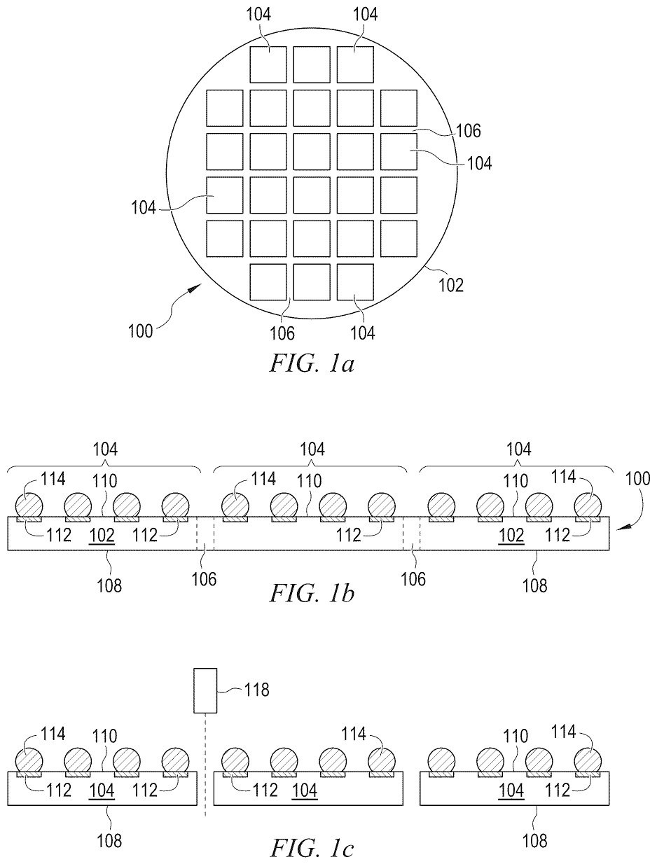

FIG. 1a shows a semiconductor wafer 100 with a base substrate material 102, such as silicon, germanium, aluminum phosphide, aluminum arsenide, gallium arsenide, gallium nitride, indium phosphide, silicon carbide, or other bulk material for structural support. A plurality of semiconductor die or electrical components 104 is formed on wafer 100 separated by a non-active, inter-die wafer area or saw street 106. Saw street 106 provides cutting areas to singulate semiconductor wafer 100 into individual semiconductor die 104. In one embodiment, semiconductor wafer 100 has a width or diameter of 100-450 millimeters (mm).

FIG. 1b shows a cross-sectional view of a portion of semiconductor wafer 100. Each semiconductor die 104 has a back or non-active surface 108 and an active surface 110 containing analog or digital circuits implemented as active devices, passive devices, conductive layers, and dielectric layers formed over or within the die and electrically interconnected according to the electrical design and function of the die. For example, the circuit may include one or more transistors, diodes, and other circuit elements formed within active surface 110 to implement analog circuits or digital circuits, such as digital signal processor (DSP), application specific integrated circuits (ASIC), memory, power devices, or other signal processing circuit. Semiconductor die 104 may also contain IPDs, such as inductors, capacitors, and resistors, for RF signal processing.

An electrically conductive layer 112 is formed over active surface 110 using physical vapor deposition (PVD), chemical vapor deposition (CVD), electrolytic plating, electroless plating process, or other suitable metal deposition process. Conductive layer 112 can be one or more layers of aluminum (Al), copper (Cu), tin (Sn), nickel (Ni), gold (Au), silver (Ag), or other suitable electrically conductive material. Conductive layer 112 operates as contact pads electrically connected to the circuits on active surface 110.

An electrically conductive bump material is deposited over conductive layer 112 using an evaporation, electrolytic plating, electroless plating, ball drop, or screen printing process. The bump material can be Al, Sn, Ni, Au, Ag, lead (Pb), bismuth (Bi), Cu, solder, and combinations thereof, with an optional flux solution. For example, the bump material can be eutectic Sn/Pb, high-lead solder, or lead-free solder. The bump material is bonded to conductive layer 112 using a suitable attachment or bonding process. In one embodiment, the bump material is reflowed by heating the material above its melting point to form balls or bumps 114. In one embodiment, bump 114 is formed over an under-bump metallization (UBM) having a wetting layer, barrier layer, and adhesion layer. Bump 114 can also be compression bonded or thermocompression bonded to conductive layer 112. Bump 114 represents one type of interconnect structure that can be formed over conductive layer 112. The interconnect structure can also use bond wires, conductive paste, stud bump, micro bump, or other electrical interconnect.

In FIG. 1c, semiconductor wafer 100 is singulated through saw street 106 using a saw blade or laser cutting tool 118 into individual semiconductor die 104. The individual semiconductor die 104 can be inspected and electrically tested for identification of known good die (KGD) or known good unit (KGU) after singulation.

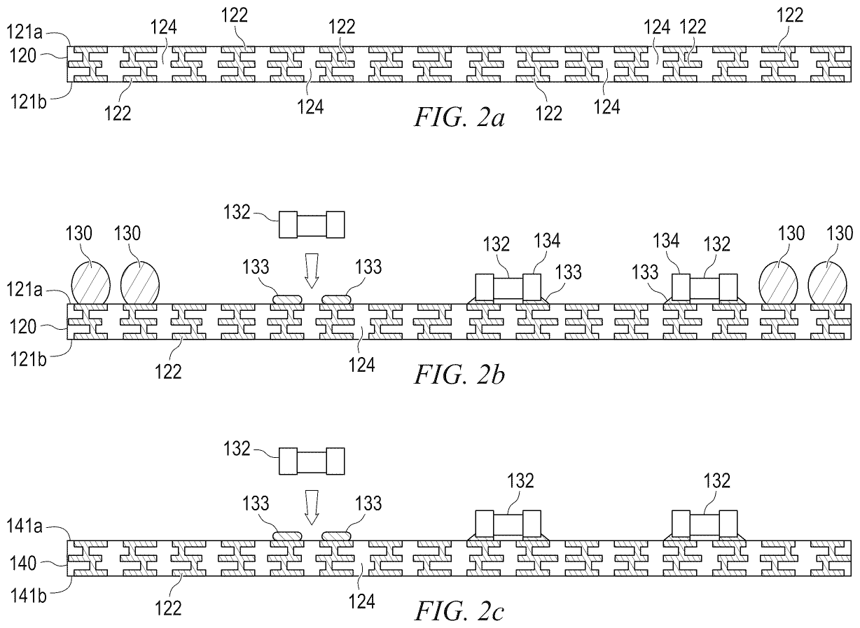

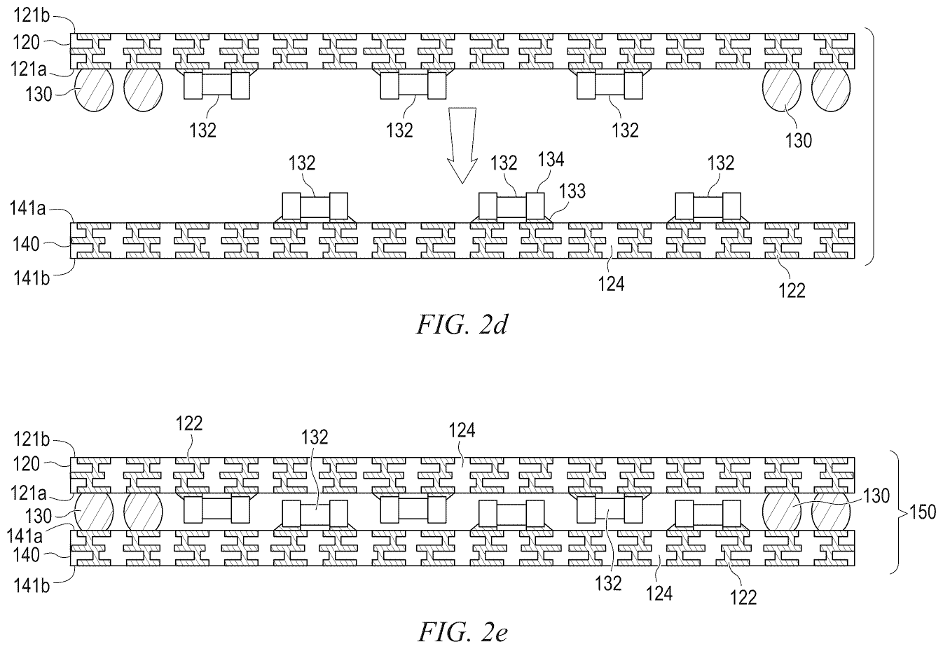

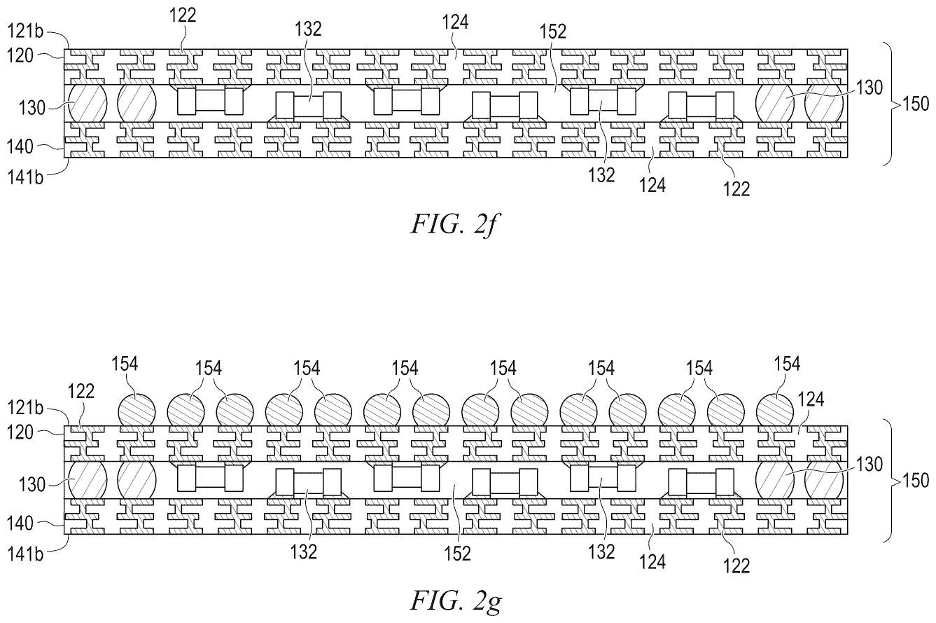

FIGS. 2a-2g illustrate the formation of a sandwich board, which will serve as the substrate for high profile and heavy electronic modules. FIG. 2a shows a substrate 120. Substrate 120 is a multi-layered interconnect substrate including conductive layers 122 and insulating layers 124. While only a single substrate 120 suitable to form a single package or module is shown, hundreds or thousands of units are commonly manufactured on, and processed as part of, a single substrate before being singulated from each other, using the same steps described herein performed en masse. A separate substrate 120 could also be used for each package being manufactured, the substrate being singulated before the steps shown hereafter and a plurality of individual substrates being placed on a common carrier for processing.

Conductive layers 122 can be one or more layers of Al, Cu, Sn, Ni, Au, Ag, or other suitable electrically conductive material. Conductive layers 122 can be formed using PVD, CVD, electrolytic plating, electroless plating, or other suitable metal deposition process. Conductive layers 122 provide horizontal electrical interconnect across substrate 120 and vertical electrical interconnect between top surface 121a and bottom surface 121b. Portions of conductive layers 122 can be electrically common or electrically isolated depending on the design and function of the package or module being formed.

Insulating layers 124 contain one or more layers of SiO2, Si3N4, SiON, Ta2O5, Al2O3, solder resist, PI, BCB, PBO, and other material having similar insulating and structural properties. Insulating layers 124 can be formed using PVD, CVD, printing, lamination, spin coating, spray coating, sintering, thermal oxidation, or another suitable process. Insulating layers 124 provide isolation between conductive layers 122. Any number of conductive layers 122 and insulating layers 124 can be interleaved over each other to form substrate 120.

Any other suitable type of package substrate or leadframe is used for substrate 120 in other embodiments. For example, substrate 120 can be a laminate interposer, PCB, wafer-form, strip interposer, leadframe, or another suitable substrate. Substrate 120 may include one or more laminated layers of polytetrafluoroethylene pre-impregnated (prepreg), FR-4, FR-1, CEM-1, or CEM-3 with a combination of phenolic cotton paper, epoxy, resin, woven glass, matte glass, polyester, and other reinforcement fibers or fabrics. Substrate 120 can also be a multi-layer flexible laminate, ceramic, copper clad laminate, glass, or semiconductor wafer including an active surface containing one or more transistors, diodes, and other circuit elements to implement analog circuits or digital circuits.

Solder bumps 130 are formed on contact pads of conductive layer 122 as described above for bumps 114. Bumps 130 are formed as one or more lines or rings of discrete bumps around the edges of substrate 120. In other embodiments, bumps 130 are also formed internal to substrate 120.

Any desired electrical components 132 to implement the electrical functionality of the semiconductor package or module being formed are mounted on surface 121a of substrate 120 in FIG. 2b, optionally including semiconductor die 104 from FIG. 1c. Electrical components 132 are disposed on surface 121a of interconnect substrate 120 and electrically and mechanically connected to conductive layers 122 by solder paste 133 that will be reflowed between terminals 134 of the components and exposed contact pads of conductive layer 122. For example, electrical components 132 can be discrete electrical devices, such as a diode, transistor, resistor, capacitor, or inductor. Electrical components 132 can include semiconductor die 104, other semiconductor die, semiconductor packages, surface mount devices, RF components, discrete active or passive electrical devices, and may include integrated passive devices (IPDs).

Electrical components 132 are positioned over substrate 120 using a pick and place operation. Electrical components 132 are brought into contact with conductive layer 122 on surface 121a of substrate 120. Terminals 134 of electrical components 132 electrically and mechanically connected to conductive layer 122 using solder or conductive paste 133. Semiconductor die 104, if used, are electrically and mechanically connected to conductive layer 122 by reflowing bumps 114.

FIG. 2c illustrates a second substrate 140, separate from the first substrate 120. Substrate 140 is formed and structured the same as substrate 120 but typically has a different electrical routing of conductive layers 122 to implement the desired circuit. Substrate 140 can be any type of substrate or interposer as described above for substrate 120. Substrates 120 and 140 can be the same or different types of substrates. Substrate 140 can be a unit substrate while substrate 120 is a panel or wafer of multiple connected units. Substrates 120 and 140 can both be unit level or panels in any combination.

Substrate 140 includes a top surface 141a and bottom surface 141b. Electrical components 132, optionally including semiconductor die 104, are mounted on surface 141a in FIG. 2c as described above for the components mounted on substrate 120 in FIG. 2b. Electrical components 132 on substrate 140 are sized and positioned to not interfere with components 132 on substrate 120 when the two substrates are sandwiched together in FIG. 2d.

FIG. 2d shows substrate 120 flipped and positioned over substrate 140. Substrate 120 is flipped so that surface 121a is oriented downward toward substrate 140 while surface 141a remains oriented upward, also toward the other substrate 120. Substrate 120 is lowered down onto substrate 140 in FIG. 2e. Bumps 130 are reflowed to electrically and mechanically connect substrates 120 and 140. Components 132 are interleaved such that, when substrate 120 is flipped, no component 132 from substrate 120 is within a footprint of a component 132 from substrate 140. When the substrates are mounted on each other, components 132 from each substrate lie within the height of each other, but do not physically contact or block each other because their layouts are laid out to avoid conflict. In other embodiments, components 132 from each substrate fall within the same footprint as each other but have reduced heights to not contact each other. In one embodiment, one or more components 132 from substrate 140 directly connects to substrate 120, or vice versa, after the substrates are stacked.

The stacking of substrates 120 and 140 completes a sandwich board 150, or simply board 150. An encapsulant or molding compound 152 is optionally deposited between substrates 120 and 140 in FIG. 2f. Encapsulant 152 is deposited using a paste printing, compression molding, transfer molding, liquid encapsulant molding, vacuum lamination, spin coating, or other suitable applicator. Encapsulant 152 can be liquid or granular polymer composite material, such as epoxy resin, epoxy acrylate, or another suitable polymer, with or without a filler. Encapsulant 152 is non-conductive, provides structural support, and environmentally protects the embedded electrical components from external elements and contaminants.

Solder bumps 154 are optionally formed on surface 121b of substrate 120 in FIG. 2g as described above for bumps 114 and 130. Bumps 154 can be formed on surface 141b of substrate 140 instead. Bumps 154 will be used to mount the finished module onto the substrate or PCB of a larger electronic device. Bumps 154 can be formed at a later or earlier stage, or another suitable interconnect structure can be formed, including leaving contact pads of conductive layer 122 exposed as a land-grid array. In other embodiments, no external interconnect is provided through board 150. Instead, a connector added in later steps is relied upon for external interconnect.

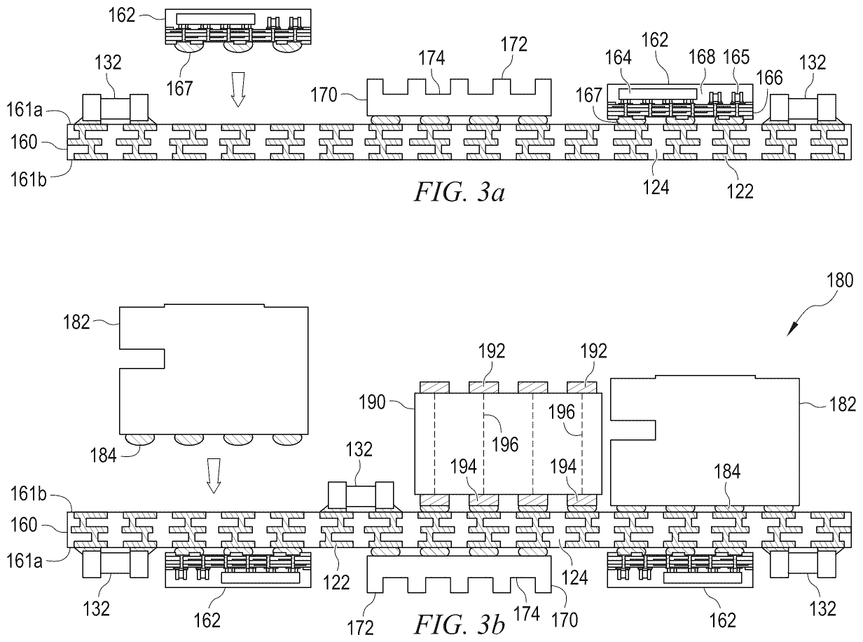

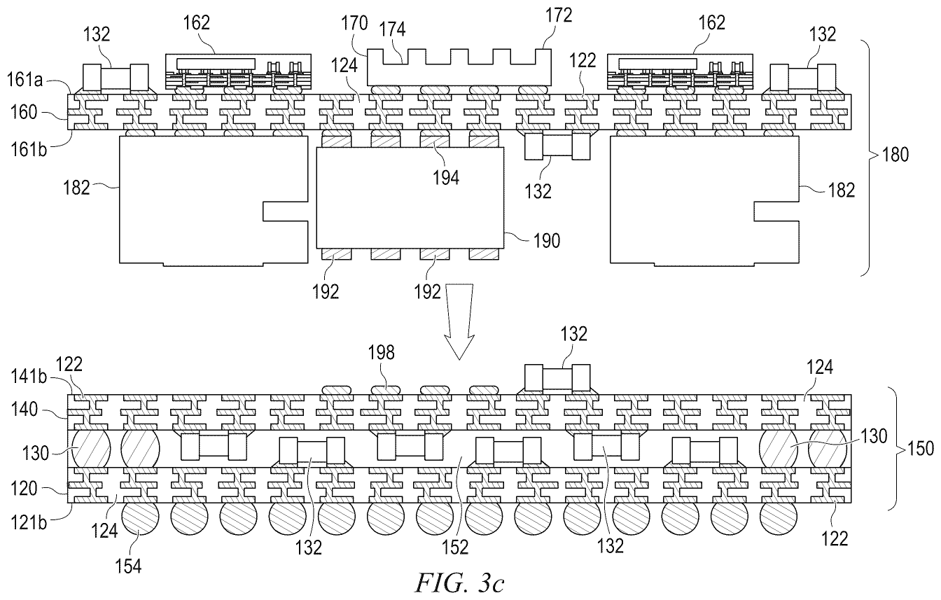

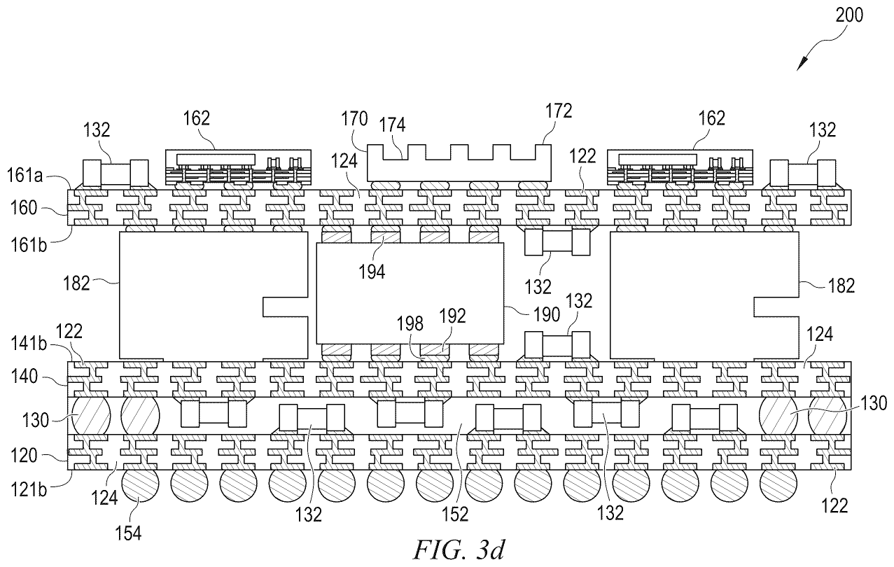

FIGS. 3a-3d illustrate the formation of electronic modules with board 150. FIG. 3a shows a top-side substrate or PCB 160. Substrate 160 is structured similarly to substrates 120 and 140 but can also be any suitable type of package substrate or interposer. A variety of components are mounted on top surface 161a first in FIG. 3a. Electrical components 132 are mounted as described above and can be any suitable type of electrical component. One or more semiconductor packages 162 is also mounted onto top surface 161a.

Semiconductor packages 162 contain semiconductor die 164 providing the primary active functionality of the modules being created. Semiconductor die 164 can be semiconductor die 104 from FIG. 1c, or another semiconductor die formed in a similar manner. Semiconductor die 164 are mounted on a substrate 166 having interleaved insulating and conductive layers similar to substrate 160, but typically finer pitched. Additional electrical components 165 can be any suitable component, such as those mentioned for electrical components 132. Electrical components 165 are mounted onto substrate 166 and electrically connected to semiconductor die 164 through the substrate. An encapsulant 168 is deposited over semiconductor die 164, components 165, and substrate 166. Semiconductor packages 162 can be any suitable type of semiconductor package. In other embodiments, bare die 104 or 164 are mounted directly to substrate 160 instead of pre-packaging the die.

A connector 170 is mounted onto surface 161a between packages 162. Connector 170 is a board-to-board (B2B) connector in one embodiment. The connector includes raised portions 172 and recesses 174 used to clasp onto a mating connector of a ribbon cable or other interconnect. The sidewalls of raised portions 172 have detents or other features to provide a clip or latching function with the corresponding connector. Connector 170 is the exclusive option for external interconnect of the module being formed in some embodiments, rather than also connecting through board 150.

In FIG. 3b, substrate 160 is flipped and more components are mounted onto surface 161b to complete a top PCB 180. In particular, two inductors 182 are mounted onto surface 161b. Inductors 182 have solder bumps 184 that are reflowed onto contact pads of conductive layer 122 to physically and electrically attach the inductors to substrate 160. Bumps 184 are electrically connected to one or more coils of inductor 182.

A pin header 190 is mounted onto substrate 160 between inductors 182. Pin header 190 includes a plurality of pins 196 extending in parallel through the header with top ends 192 and bottom ends 194 exposed at the top and bottom of a plastic body. Pins 196 are physically and electrically connected to substrate 160 by solder paste in one embodiment. Header 190 keeps pins 196 oriented in parallel with each other so that the top ends 192 remain predictably aligned directly over respective bottom ends 194. Header 190 can include a single line of pins 196 or a 2-dimensional grid of pins with multiple columns and rows. Any other type of vertical interconnect structure can be used instead of pin header 190. Any other desired electrical components 132 can be mounted onto surface 161b as well.

Inductors 182 are high profile and heavy components compared to electrical components 132, semiconductor die 104, semiconductor packages 162, and other components being packaged together with the inductors. High profile refers to the height of inductors 182 being significantly greater than the other components. In one embodiment, high profile indicates a height over three times greater than the height of a semiconductor die also being packaged with the high profile component. Heavy indicates a weight that is significantly greater than other components being packaged together with the heavy component. In one embodiment, heavy indicates a weight over three times greater than the weight of a semiconductor die also being packaged with the heavy component. Inductors 182 are high profile and heavy components. The same manufacturing process flow disclosed herein can be used to create modules with any suitable high profile or heavy component.

In FIG. 3c, the fully populated top PCB 180 is flipped and disposed over sandwich board 150. Solder bumps or paste 198 is disposed on contact pads of conductive layer 122 exposed at surface 141b where pins 196 will connect to substrate 140. In some embodiments, solder paste 198 is also printed under inductors 182 to electrically connect the inductors to board 150, such that board 150 is connected to substrate 160 through the inductor coils. Any additional electrical components 132 can be mounted onto surface 141b as desired. Components 132 on surface 141b are placed in locations where gaps between inductors 182, pin header 190, and components 132 of top PCB 180 are located. In some embodiment, substrate 160 is singulated prior to mounting onto board 150. In other embodiments, substrate 160 and board 150 are mounted together as panels and singulated together. Substrate 160 and board 150 can also both be singulated prior to mounting together.

When top PCB 180 is placed on board 150 in FIG. 3d, the top surfaces of inductors 182, opposite substrate 160, rest on surface 141b. The heights of inductors 182 being identical holds substrate 160 parallel to substrate 140 during reflow. Having two inductors 182 gives multiple points of contact to increase stability. The inductors extend into and out of the page, which provides a two-dimensional base. Having two dimensions of physical contact between substrate 160 and 140 increases stability during reflow and helps ensure the substrates are held parallel. Solder 198 is reflowed to physically and electrically connect pin header 190 to substrate 140. An adhesive, underfill, or encapsulant can be used between inductors 182 and substrate 140 to physically support the combination of board 150 and top PCB 180 in use.

The combination of top PCB 180 and board 150 creates a module 200. Board 150, top PCB 180, or both are singulated if necessary using a router, laser cutting tool, saw blade, or other suitable means to separate a plurality of modules 200 that were formed together. Module 200 is a package or module with heavy and high profile components, i.e., inductors 182. Top PCB 180 individually, and module 200 with top PCB 180, can each be considered heavy and high profile due to including heavy and high profile components. In addition, module 200 can be considered heavy and high profile itself due to being heavy or high profile in comparison with other components that will ultimately go into the same larger electronic device along with module 200.

Module 200 is a heavy and high profile module manufactured with a simplified process that reduces manufacturing cost. Module 200 is manufactured in a way that reduces overall package size compared to other methods for packaging high profile and heavy components in the prior art.

In one embodiment, packages 162 are voltage-regulating modules (VRM) that operate as part of a switch-mode power supply. The components of module 200 can be considered as multiple independent vertically stacked modules. For instance, the illustrated embodiment has two stacked voltage-regulating modules that pair an inductor 182 with a VRM in semiconductor package 162 and a connector module that pairs connector 170 with pin header 190 for external interconnect from board 150. Stacks can be created for other purposes, such as an MPS module along with the two illustrated VRM modules. An MPS module combines power semiconductors, passive components, and drivers in one package or vertical column within a package. The MPS module converts and controls power for automotive, renewable energy, and data center applications. MPS modules reduce power loss, improve heat management, and simplifies system design.

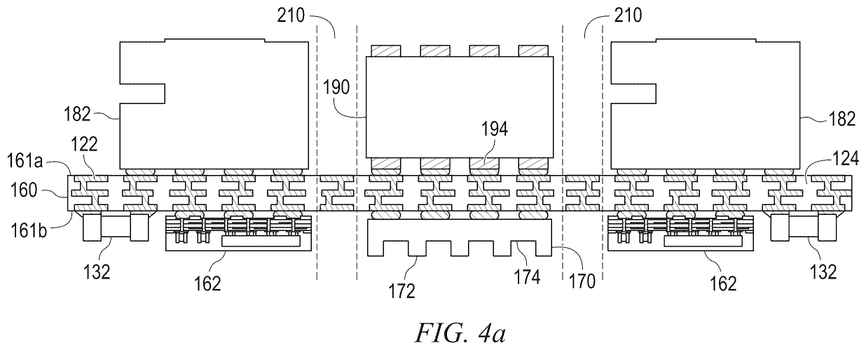

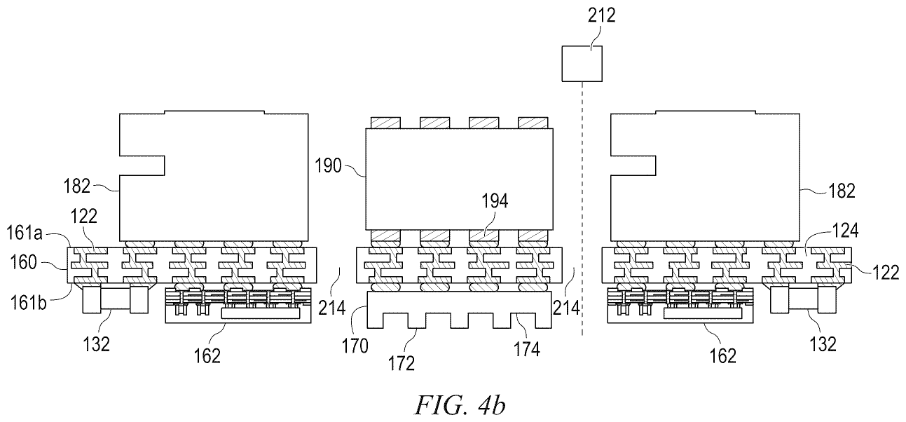

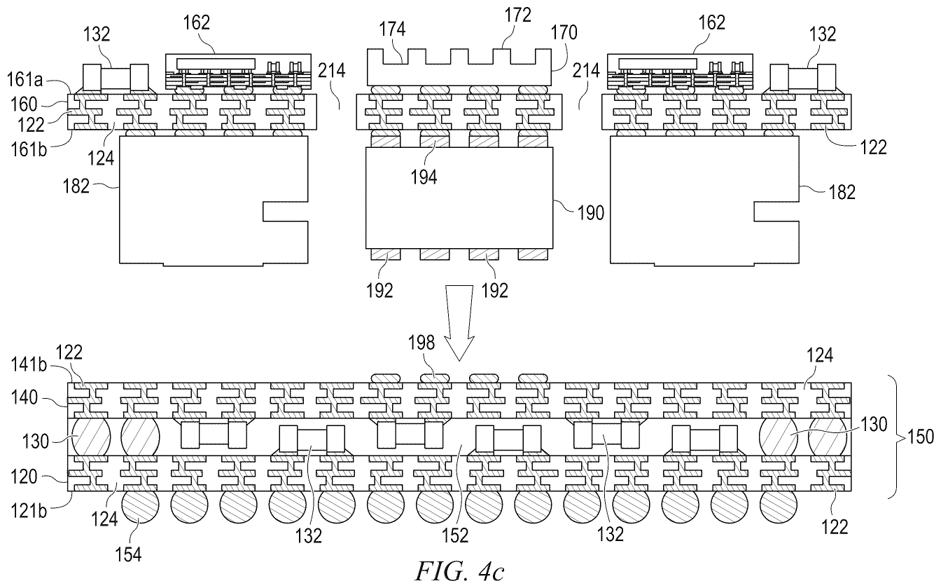

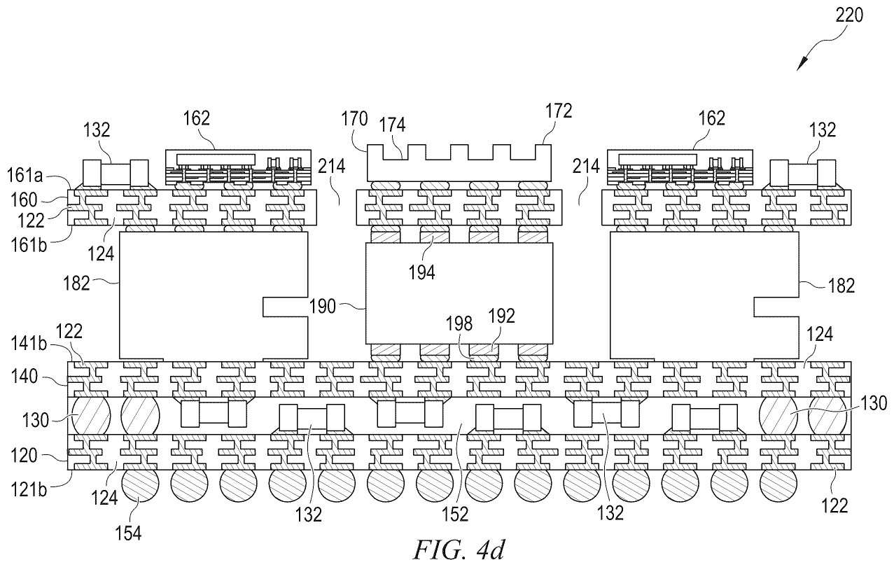

FIGS. 4a-4d illustrate an alternative process flow. Continuing from FIG. 3b, the components on substrate 160 are laid out to provide areas 210 free of components. Areas 210 are like partial saw streets that extend through the middle of the units. A router 212, saw blade, laser, or other suitable mechanism is used to cut through areas 210 and form trenches or slots 214 completely through substrate 160 in FIG. 4b. Trenches 214 extend into and out of the page of FIG. 4b to create physical isolation between inductors 182 and pin header 190. Trenches 214 do not extend completely across the saw streets between, or a frame around each unit so that the portions of substrate 160 on opposite sides of each slot 214 remain physically attached to each other. Slots 214 can form a corner to run adjacent to multiple sides of an inductor 182. Slot 214 allows process scaling to integrate more passive components and connectors.

In FIG. 4c, substrate 160 with slots 214 and inductors 182 is disposed over board 150 and mounted in FIG. 4d. Solder 198 is reflowed to physically and mechanically attach substrate 160 to board 150 and complete a module 220. Multiple modules 220 are formed together and then singulated in some embodiments. The separate portions of substrate 160 remain interconnected both physically and electrically around slots 214 in some embodiments. In other embodiments, singulating fully separates the multiple portions of substrate 160 by removing the portions within the saw streets that had held them together. Full physical separation between the portions of substrate 160 by slots 214 provides improved physical isolation for the connector 170 section from inductors 182. Each separate portion of substrate 160 and its attached components are a submodule, e.g., a VRM submodule with a VRM subpackage 162 and inductor 182 stacked, or a connector submodule with connector 170 and pin header 190 stacked.

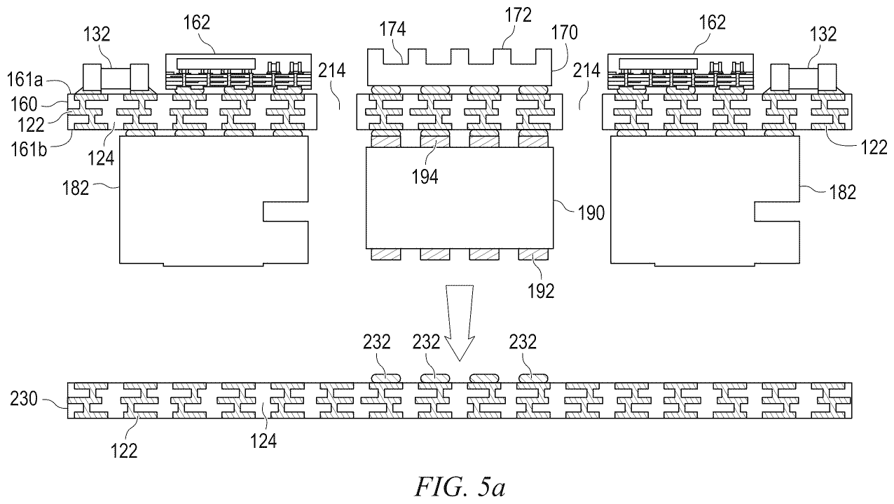

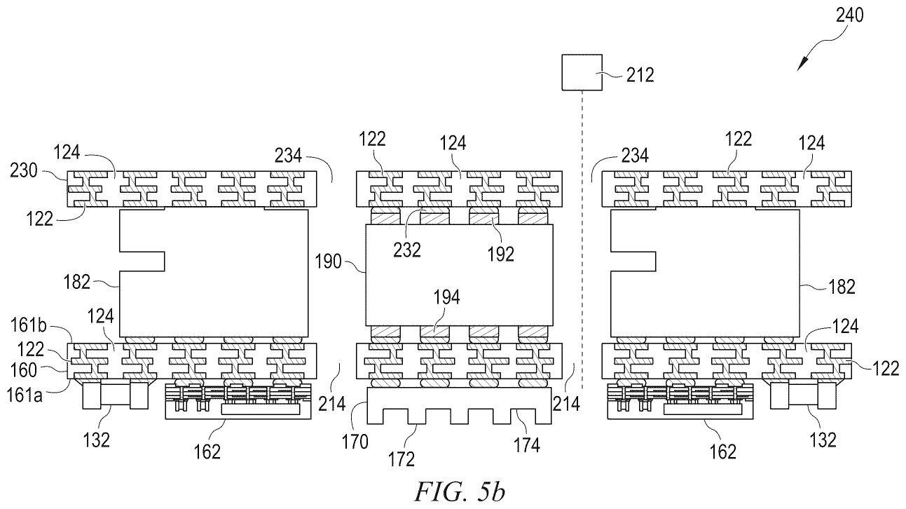

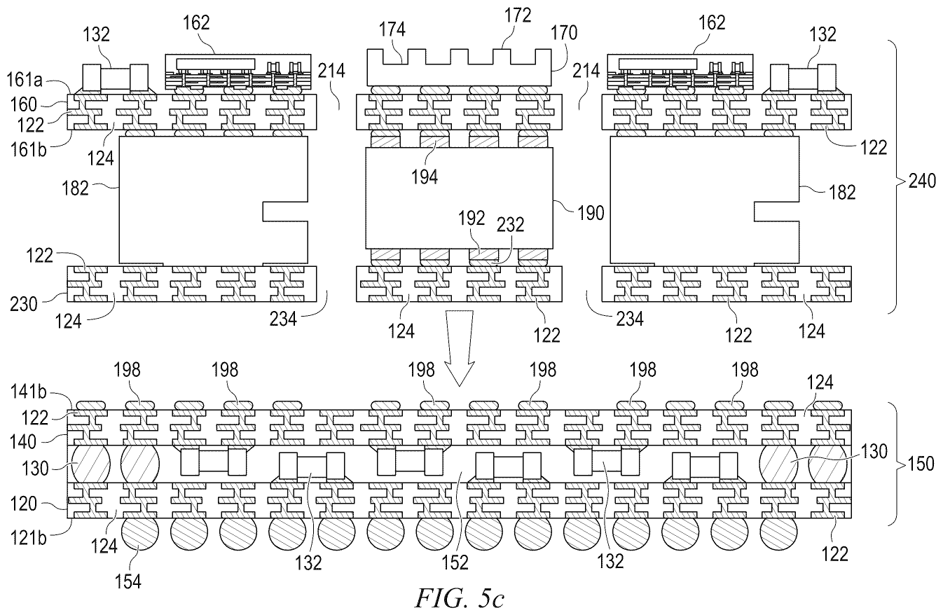

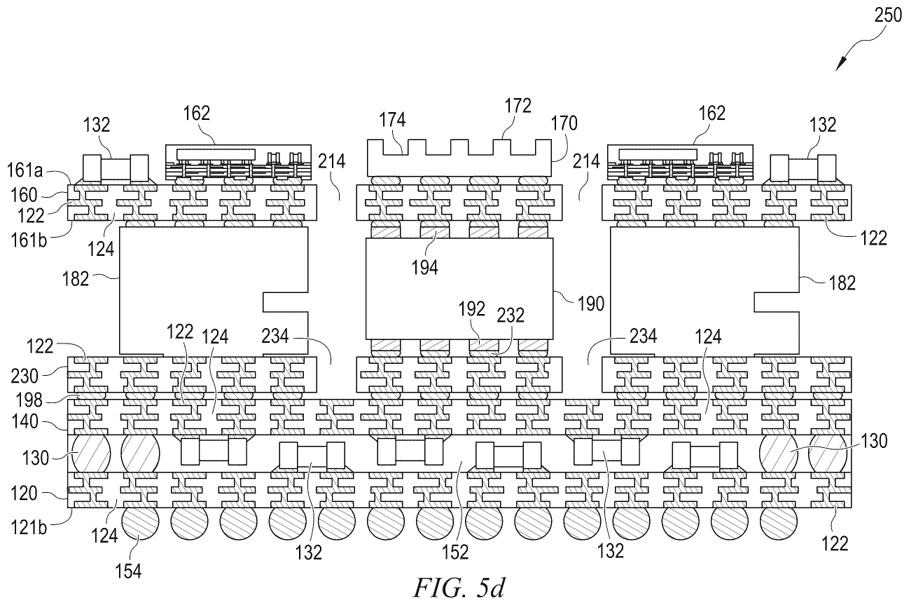

FIGS. 5a-5d illustrate another process flow for forming a high profile and heavy module on board 150. In FIG. 5a, continuing from FIG. 4b after the formation of slots 214, substrate 160 is disposed over another substrate 230 with inductors 182 disposed between substrates 160 and 230. Solder paste 232 is printed on contact pads of substrate 230 where pin header 190 will connect to substrate 230. Solder paste 232 is reflowed to physically and electrically connect substrate 230 to substrate 160. Additional adhesive, underfill, or encapsulant can be deposited between inductors 182 and substrate 230 to add a physical attachment directly between substrate 230 and the inductors.

In FIG. 5b, an upper module 240 is completed by flipping substrate 160 and 230 and cutting slots 234 into substrate 230 using router 212. Trenches 234 may or may not fully disconnect the sections of substrate 230 from each other. In one embodiment, trenches 234 completely separate the portions of substrate 230 while substrate 160 remains connected as one larger substrate.

In FIG. 5c, module 240 is disposed over board 240 with substrate 230 oriented toward the board. Substrate 230 is set on board 150 in FIG. 5d to complete a module 250. Solder paste 198 is reflowed between substrates 230 and 140 to physically and electrically couple the substrates together. Modules 250 are singulated from each other if necessary to complete the modules. Singulation completely separates the portions of substrate 230 from each other and the portions of substrate 160 from each other in some embodiments. Using substrate 230 separate from substrate 140 allows inductors or connectors to be applied using various interposer materials without being affected by the structure or materials of the underlying board 150. In some embodiments, multiple separate substrates 230 are used, rather than a single large substrate that is later separated, so that different materials can be used for the different vertical stacks.

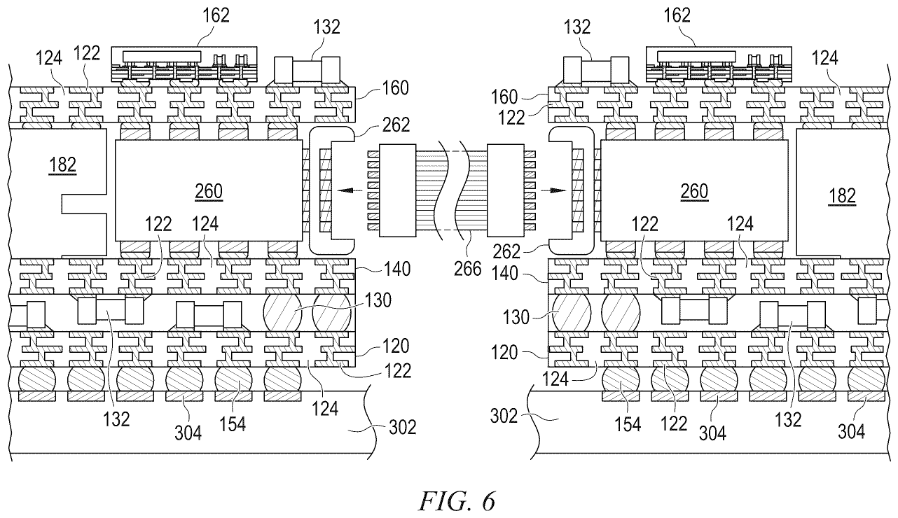

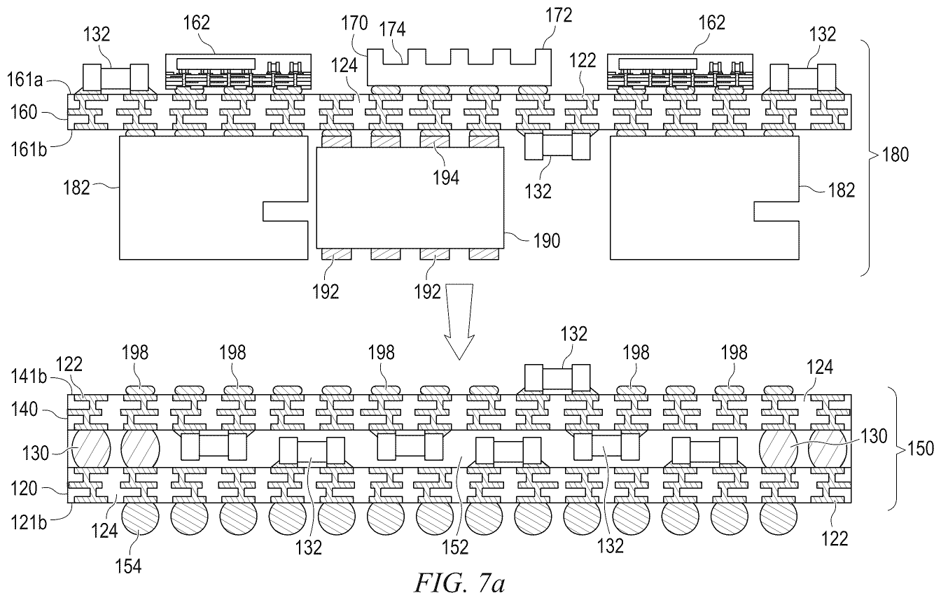

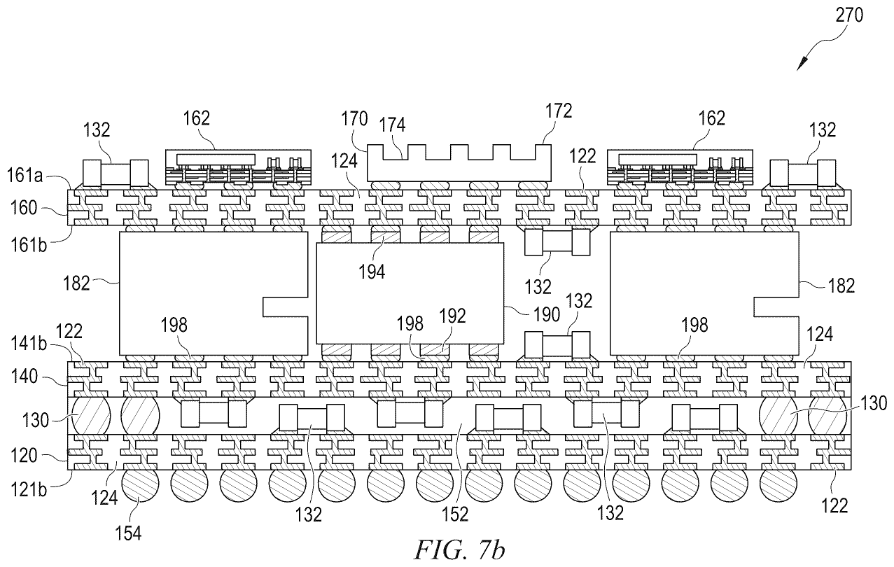

FIG. 6 illustrates an embodiment with pin headers 260 in addition to or instead of pin headers 190. Pin headers 260 are similar to pin headers 190, with the addition of a connector 262 formed on the side of the pin header to allow a ribbon cable 266 or other type of interconnect structure to be connected to the side of the module directly to the pin header. Ribbon cable 266 physically clips into connector 262 and thereby electrically connects to the pins of pin header 260. Two adjacent modules with pin headers 260 can directly communicate with each other through ribbon cable 266, thus improving latency and bandwidth between the modules and reducing routing congestion of the underlying substrate or PCB. In some embodiments, connector 262 is used for inter-module communication while a connector 170 on top of one or both modules is used for external interconnect to other systems. In other embodiments, a module has no connector 170 and only connector 262 is used for external interconnect, either to another like module, a different external system, or both. Pin header 260 with connector 262 can be used with any of the above or below embodiments.

FIGS. 7a and 7b illustrate an embodiment with inductors 182 having electrical terminals on both the bottom and the top of the inductors. Solder 198 is deposited under inductors 182 in FIG. 7a. When solder 198 is reflowed in FIG. 7b, a physical and electrical connection between substrate 140 and inductors 182 is solidified. Board 150 is connected to the components on substrate 160 through the coils of inductors 182 in addition to the connection provided by pin header 190. Any of the above or below embodiments can add a vertical electrical connection through inductors 182 or other high profile and heavy components.

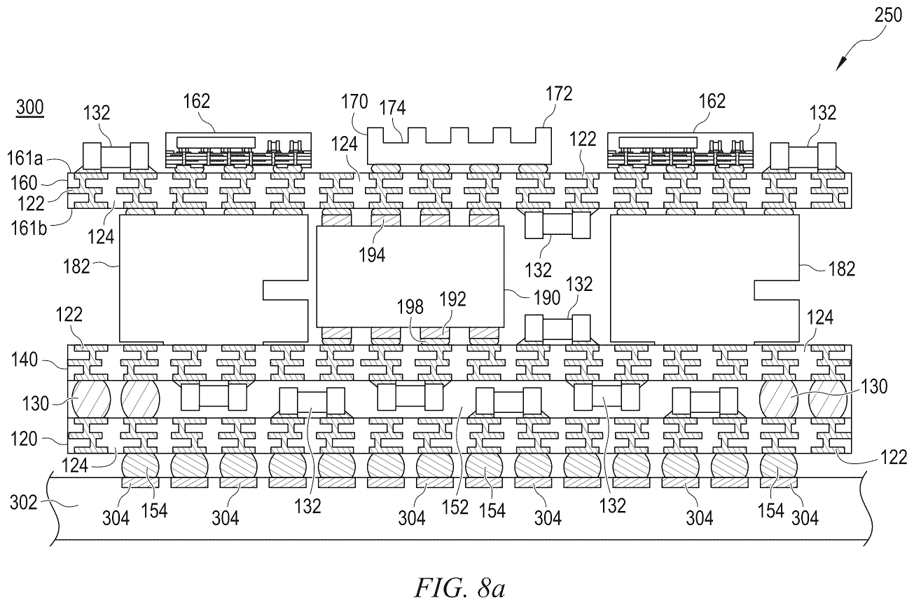

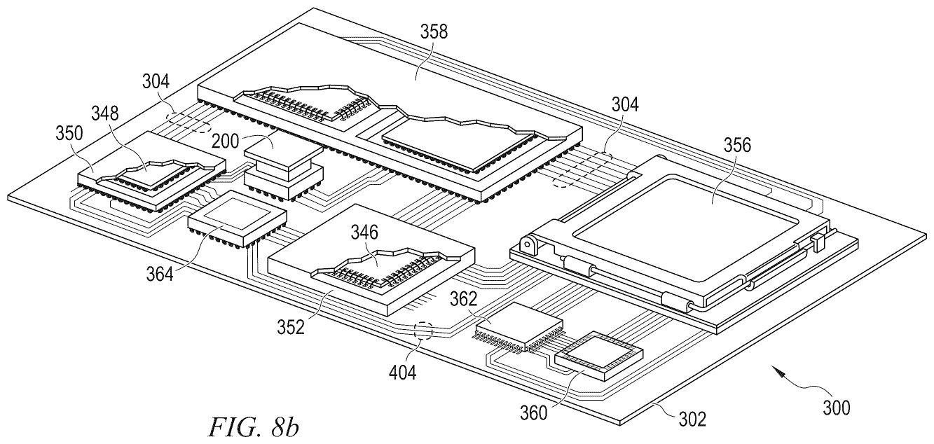

FIGS. 8a and 8b illustrate integrating the above-described modules, e.g., module 200, into a larger electronic device 300. FIG. 8a illustrates a partial cross-section of module 200 mounted onto a printed circuit board (PCB) or other substrate 302 as part of electronic device 300. Solder bumps 154 are reflowed onto conductive layer 304 of PCB 302 to physically attach and electrically connect module 200 to the PCB. In other embodiments, thermocompression or another suitable attachment and connection methods are used. In some embodiments, an adhesive or underfill layer is used between module 200 and PCB 302. The components of module 200 are electrically coupled to conductive layer 304 through substrates 120, 140, and 160.

FIG. 8b illustrates electronic device 300 having a chip carrier substrate or PCB 302 with a plurality of semiconductor packages disposed on a surface of PCB 302, including module 200. Electronic device 300 can have one type of semiconductor package, or multiple types of semiconductor packages, depending on the application.

Electronic device 300 can be a stand-alone system that uses the semiconductor packages to perform one or more electrical functions. Alternatively, electronic device 300 can be a subcomponent of a larger system. For example, electronic device 300 can be part of a tablet, cellular phone, digital camera, communication system, or other electronic device. Alternatively, electronic device 300 can be a graphics card, network interface card, or other signal processing card that can be inserted into a computer. The semiconductor package can include microprocessors, memories, ASICs, logic circuits, analog circuits, RF circuits, discrete devices, or other semiconductor die or electrical components. Miniaturization and weight reduction are essential for the products to be accepted by the market. The distance between semiconductor devices may be decreased to achieve higher density. PCB 302 may have a more irregular shape to fit conveniently into more ergonomic and smaller device shells.

In FIG. 8b, PCB 302 provides a general substrate for structural support and electrical interconnect of the semiconductor packages disposed on the PCB. Conductive signal traces 304 are formed over a surface or within layers of PCB 302 using evaporation, electrolytic plating, electroless plating, screen printing, or other suitable metal deposition process. Signal traces 304 provide for electrical communication between each of the semiconductor packages, mounted components, and other external system components. Traces 304 also provide power and ground connections to each of the semiconductor packages.

In some embodiments, a semiconductor device has two packaging levels. First level packaging is a technique for mechanically and electrically attaching the semiconductor die to an intermediate substrate. Second level packaging involves mechanically and electrically attaching the intermediate substrate to the PCB. In other embodiments, a semiconductor device may only have the first level packaging where the die is mechanically and electrically disposed directly on the PCB.

For the purpose of illustration, several types of first level packaging, including bond wire package 346 and flipchip 348, are shown on PCB 302. Additionally, several types of second level packaging, including ball grid array (BGA) 350, bump chip carrier (BCC) 352, land grid array (LGA) 356, multi-chip module (MCM) or SIP module 358, quad flat non-leaded package (QFN) 360, quad flat package 362, and embedded wafer level ball grid array (eWLB) 364 are shown disposed on PCB 302. In one embodiment, eWLB 364 is a fan-out wafer level package (Fo-WLP) or a fan-in wafer level package (Fi-WLP).

Depending upon the system requirements, any combination of semiconductor packages, configured with any combination of first and second level packaging styles, as well as other electrical components, can be connected to PCB 302. In some embodiments, electronic device 300 includes a single attached semiconductor package, while other embodiments call for multiple interconnected packages. By combining one or more semiconductor packages over a single substrate, manufacturers can incorporate pre-made components into electronic devices and systems. Because the semiconductor packages include sophisticated functionality, electronic devices can be manufactured using less expensive components and a streamlined manufacturing process. The resulting devices are less likely to fail and are less expensive to manufacture, which lowers costs up and down the supply chain.

While one or more embodiments of the present invention have been illustrated in detail, the skilled artisan will appreciate that modifications and adaptations to those embodiments may be made without departing from the scope of the present invention as set forth in the following claims.

What is claimed:

1. A method of making a semiconductor device, comprising:
providing a first substrate;
disposing a first semiconductor package over a first surface of the first substrate;
disposing a second semiconductor package over the first surface of the first substrate;
disposing a connector over the first surface of the first substrate;
disposing a first inductor over a second surface of the first substrate opposite the first semiconductor package;
disposing a second inductor over the second surface of the first substrate opposite the second semiconductor package;
disposing a pin header over the second surface of the first substrate opposite the connector; and
disposing the first substrate over a board with the first inductor and second inductor between the first substrate and board.

2. The method of claim 1, wherein the pin header includes a connector.

3. The method of claim 1, further including:
forming a first slot in the first substrate between the first inductor and pin header; and
forming a second slot in the first substrate between the second inductor and pin header.

4. The method of claim 1, further including forming the board by:
providing a second substrate;
disposing a first electrical component over the second substrate;
providing a third substrate;
disposing a second electrical component over the third substrate; and
mounting the second substrate to the third substrate with the first electrical component and second electrical component between the second substrate and third substrate.

5. The method of claim 1, further including:
disposing the first substrate over a second substrate with the first inductor and second inductor between the first substrate and second substrate; and
mounting the second substrate to the board.

6. The method of claim 5, further including:
forming a first slot in the first substrate between the first inductor and pin header;
forming a second slot in the first substrate between the second inductor and pin header;
forming a third slot in the second substrate between the first inductor and pin header; and
forming a fourth slot in the second substrate between the second inductor and pin header.

7. A method of making a semiconductor device, comprising:
providing a first substrate;
disposing a semiconductor die over the first substrate;
disposing an inductor over the first substrate opposite the semiconductor die; and
disposing the first substrate over a board with the inductor between the first substrate and board.

8. The method of claim 7, further including disposing a pin header between the first substrate and board.

9. The method of claim 8, wherein the pin header includes a connector.

10. The method of claim 7, further including forming a slot in the first substrate adjacent to the inductor.

11. The method of claim 7, further including forming the board by:
providing a second substrate;
disposing a first electrical component over the second substrate;
providing a third substrate;
disposing a second electrical component over the third substrate; and
mounting the second substrate to the third substrate with the first electrical component and second electrical component between the second substrate and third substrate.

12. The method of claim 7, further including:
disposing the first substrate over a second substrate with the inductor between the first substrate and second substrate; and
mounting the second substrate to the board.

13. The method of claim 12, further including:
forming a first slot in the first substrate adjacent to the inductor; and
forming a second slot in the second substrate adjacent to the inductor.

14. A semiconductor device, comprising:
a first substrate;
a first inductor disposed over a first surface of the first substrate;
a second inductor disposed over the first surface of the first substrate;
a pin header disposed over the first surface of the first substrate;
a first semiconductor package disposed over a second surface of the first substrate opposite the first inductor;
a second semiconductor package disposed over the second surface of the first substrate opposite the second inductor;
a connector disposed over the second surface of the first substrate opposite the pin header; and
a board mounted to the first inductor, second inductor, and pin header.

15. The semiconductor device of claim 14, wherein the pin header includes a connector.

16. The semiconductor device of claim 14, wherein the board includes:
a second substrate;
a first electrical component disposed over the second substrate;
a third substrate; and
a second electrical component disposed over the third substrate, wherein the second substrate is mounted to the third substrate with the first electrical component and second electrical component between the second substrate and third substrate.

17. The semiconductor device of claim 14, further including a second substrate disposed between the board on a first side of the second substrate and the first inductor and second inductor on a second side of the second substrate.

18. The semiconductor device of claim 17, further including:
a first slot formed in the first substrate between the first inductor and pin header;
a second slot formed in the first substrate between the second inductor and pin header;
a third slot formed in the second substrate between the first inductor and pin header; and
a fourth slot formed in the second substrate between the second inductor and pin header.

19. The semiconductor device of claim 14, further including:
a first slot formed in the first substrate between the first inductor and pin header; and
a second slot formed in the first substrate between the second inductor and pin header.

20. A semiconductor device, comprising:
a first substrate;
an inductor disposed over the first substrate;
a semiconductor die disposed over the first substrate opposite the inductor; and
a board mounted to the inductor.

21. The semiconductor device of claim 20, further including a pin header disposed between the first substrate and board.

22. The semiconductor device of claim 21, further including a slot formed in the first substrate adjacent to the inductor.

23. The semiconductor device of claim 20, wherein the board includes:
a second substrate;
a first electrical component disposed over the second substrate;
a third substrate; and
a second electrical component over the third substrate, wherein the second substrate is mounted to the third substrate with the first electrical component and second electrical component between the second substrate and third substrate.

24. The semiconductor device of claim 20, further including a second substrate mounted to the inductor opposite the first substrate, wherein the inductor is mounted to the board through the second substrate.

25. The semiconductor device of claim 24, further including:
a first slot formed in the first substrate adjacent to the inductor; and
a second slot formed in the second substrate adjacent to the inductor.
